(19) United States
(12) Patent Application Publication
(10) Pub. No.: US 2024/0195386 A1
(43) Pub. Date: Jun. 13, 2024

(54) ADDITION OF BORON TO AlN AND AlScN PIEZOELECTRIC MATERIALS

(71) Applicant: Qorvo US, Inc., Greensboro, NC (US)

(72) Inventor: Kevin Talley, Bend, OR (US)

(21) Appl. No.: 18/525,379

(22) Filed: Nov. 30, 2023

Related U.S. Application Data
(60) Provisional application No. 63/386,666, filed on Dec. 8, 2022.

(51) Int. Cl. H03H 9/54; H03H 9/02

(52) U.S. Cl. CPC H03H 9/54; H03H 9/02015

(57) ABSTRACT

A piezoelectric bulk acoustic wave (BAW) filter is provided. The BAW filter includes a piezoelectric bulk acoustic wave (BAW) filter. The BAW filter includes a first electrode disposed over a substrate, a piezoelectric layer disposed over the first electrode, and a second electrode disposed over the piezoelectric layer. The piezoelectric layer comprises Al_{z}Sc_{y}BₓN, z is equal to (1−y−x), x is greater than 0, y is equal to or greater than 0, and a sum of x and y is less than or equal to 1.

### RELATED APPLICATIONS

This application claims priority to U.S. Provisional Patent Application No. 63/386,666, filed Dec. 8, 2022, which is incorporated by reference herein in its entirety.

### FIELD OF THE INVENTION

This disclosure relates to bulk acoustic wave (BAW) filters with piezoelectric materials containing boron. In particular, this disclosure relates to adding boron to AlN and AlScN used in piezoelectric BAW filters.

### BACKGROUND

The rapid advances in fifth generation (5G) technology have created high demands in radio frequency (RF) filters. Acoustic wave technology has been used in the 5G technology as a solution for achieving high-performance RF filters of lower cost and smaller device size. Bulk acoustic wave (BAW) filters have the potential to be used in high-quality RF filters for their lower insertion loss and better selectivity in the middle and high frequency bands. BAW filters often include piezoelectric materials as the functional layer. The piezoelectric materials used in BAW filters often include aluminum nitride (AlN) and aluminum scandium nitride (AlScN).

However, the material choices for BAW filters are limited. For example, the incorporation of scandium into AlScN can have certain benefits such as increased piezoelectric coupling and increased bandwidth, but scandium is often costly and difficult to produce in common manufacturing means, and has an unreliable supply chain. Thus, it is important to diversify the material pallet in piezoelectric materials for BAW filters such that the BAW filters can be built at lower cost with higher levels of manufacturability.

### SUMMARY

Aspects of the disclosure include a piezoelectric bulk acoustic wave (BAW) filter. The BAW filter includes a first electrode disposed over a substrate, a piezoelectric layer disposed over the first electrode, and a second electrode disposed over the piezoelectric layer. The piezoelectric layer comprises Al_{z}Sc_{y}Bₓ^{N}, z is equal to (1−y−x), x is greater than 0, y is equal to or greater than 0, and a sum of x and y is less than or equal to 1.

In some embodiments, the piezoelectric layer has a wurtzite structure.

In some embodiments, the piezoelectric layer has a thickness between about 50 nm and about 10 μm.

In some embodiments, x is less than 0.8.

In some embodiments, x is equal to half a value of y.

In some embodiments, y is greater than or equal to 0.43.

In some embodiments, y is equal to 0.

In some embodiments, x is between about 0.08 and about 0.12, and y is between about 0.41 and about 0.47.

In some embodiments, x is between about 0.08 and about 0.12, and y is between about 0.43 and 0.47.

In some embodiments, x is between about 0.13 and about 0.15, and y is between about 0.53 and about 0.57.

In some embodiments, x is between about 0.18 and about 0.22, and y is between about 0.38 and about 0.42.

In some embodiments, x is between about 0.23 and about 0.27, and y is between about 0.48 and about 0.52

In some embodiments, x is between about 0.28 and about 0.32, and y is between about 0.58 and about 0.62.

Aspects of the disclosure provides a method for improving a figure of merit for a piezoelectric bulk acoustic wave (BAW) filter having a piezoelectric layer of Al_{z}Sc_{y}BₓN. The method includes: increasing a value of x, and maintaining a wurtzite crystal structure of the piezoelectric layer. In some embodiments, x is greater than 0, y is equal to or greater than 0, a sum of x and y is less than or equal to 1, and a value of z is equal to (1−x−y).

In some embodiments, the value of x is equal to half a value of y.

In some embodiments, y is less than or equal to 0.43.

In some embodiments, x is less than or equal to 0.8.

In some embodiments, y is equal to 0.

In some embodiments, y is between about 0.43 and 0.47, and x is between about 0.08 and about 0.12.

In some embodiments, y is between about 0.53 and about 0.57, and x is between about 0.13 and about 0.17

### BRIEF DESCRIPTION OF THE DRAWINGS

FIG. 1 is a diagram representing a BAW filter, according to embodiments of the present disclosure.

FIG. 2 illustrates a metastable heterostructural alloy phase space showing AlScN, AIBN, and AlScBN, according to embodiments of the present disclosure.

FIG. 3 illustrates ball and stick crystal models showing c-axis oriented wurtzite crystallites of (a) AlN, (b) AlScN, (c) AIBN, and (d) AlScBN, according to embodiments of the present disclosure.

FIG. 4 shows the internal wurtzite parameter (u).

### DETAILED DESCRIPTION

The following detailed description is illustrative in nature and is not intended to limit the scope, applicability, or configuration of inventive embodiments disclosed herein in any way. Rather, the following description provides practical examples, and those skilled in the art will recognize that some of the examples may have suitable alternatives. Embodiments will hereinafter be described in conjunction with the appended drawings, which are not to scale (unless so stated), wherein like numerals/letters denote like elements. However, it will be understood that the use of a number to refer to a component in a given drawing is not intended to limit the component in another drawing labeled with the same number. In addition, the use of different numbers to refer to components in different drawings is not intended to indicate that the different numbered components cannot be the same or similar to other numbered components. Examples of constructions, materials, dimensions and fabrication processes are provided for select elements and all other elements employ that which is known by those skilled in the art.

Reference will now be made in greater detail to various embodiments of the subject matter of the present disclosure, some embodiments of which are illustrated in the accompanying drawings.

Piezoelectric materials used in BAW filters are evaluated using various material parameters, which can indicate the material quality and/or resonant wavelengths of BAW filters. For example, the electromechanical coupling coefficient (k²) is the efficiency of the electrical to mechanical energy coupling and influences the bandwidth of the resulting filter; the mechanical quality factory (Q) is related to various intrinsic and extrinsic material properties and influences the insertion loss of the resulting BAW filters; the dielectric constant (ε) is related to the electrical energy storage capacity and affects the capacitance of the BAW filters; and the acoustic velocity (V_{L}) and the density (ρ) determine the acoustic impedance of the material, which influences the acoustic energy confinement of the BAW filters. All these parameters create a complex optimization problem for the designing of BAW filters, and the piezoelectric material choices for balancing competing property effects can be limited. For piezoelectric materials the crystal structure must support piezoelectricity, which for these materials means they must exhibit the wurtzite crystal structure.

For example, AlN has a k² maximum of about 7%. The use of AlScN heterostructural wurtzite alloys has created opportunities for BAW filters with increased bandwidths though an increased piezoelectric k² greater than 15%. The increase in coupling can cause negative impacts to other material properties of AlScN, such as lattice softening and manufacturing cost. The lattice softening in AlScN wurtzite materials is driven by the energetic competition between the rock salt and wurtzite structures, and weakness of the scandium nitride bonds, which results in lower mechanical quality of the BAW filters and greater filter-caused insertion loss. The increased cost of AlScN is often driven by the scarcity of scandium, low volume supply chain, and complexity of manufacturing large-area AlSc alloy targets.

The present disclosure provides piezoelectric materials for BAW filters with improved material properties. In embodiments of the present disclosure, boron (B) is added into AlN and AlScN to form AlBN and AlScBN heterostructural wurtzite alloys, respectively. The disclosed AlBN and AlScBN have improved material properties as piezoelectric materials while maintaining desirable piezoelectric effects. The disclosed binary AlBN heterostructural wurtzite alloys can provide a similar increased coupling coefficient as AlScN without lattice softening and increased cost. Compared to AlN, the disclosed AlBN heterostructural wurtzite alloy has a similar structure, but the additional boron nitride bonds are stronger than the aluminum nitride bonds they replace. The additional boron nitride bonds increase the hardness (e.g., mechanical strength) and piezoelectric coupling of the AIBN. The supply chain for boron is also much more robust than that for scandium, resulting in less costly and risky manufacturing dependencies. In some embodiments, the concentration of BN in AlBN is equal to or less than 0.8, e.g., y being equal to or less than 0.8 in Al_{1-y}B_{y}N. In some embodiments, the concentration of BN in AlBN is equal to or less than 0.5, e.g., y being equal to or less than 0.5 in Al_{1-y}B_{y}N.

The disclosed ternary AlScBN heterostructural wurtzite alloy stabilizes the wurtzite phase to much higher scandium concentrations while maintaining similar piezoelectric properties and increasing the mechanical hardness. For example, the disclosed AlScBN can improve the phase stability at higher levels of Sc than currently achievable with AlScN, and can partially compensate for the reduced lattice stiffness caused by scandium incorporation. In AlScBN, the lattice strain caused by the larger size of Sc is compensated by opposing lattice strain imparted by the smaller size of B, resulting in a wurtzite phase that is stable at higher ScN concentrations than possible without B. For example, in AlScBN, the scandium concentration can be higher than 43%, which is a phase stability barrier without the incorporation of B. Analysis of the ionic sizes of Sc³⁺ (0.745 Å), B³⁺ (0.11 Å), and Al³⁺ (0.535 Å) shows that an alloying ratio for Sc:B near 2:1 may result in near neutral lattice strain due to the Al-B size difference being nearly two times greater than the Al—Sc size difference. In some embodiments, the concentration of Sc in AlScBN is greater than or equal to 0.43. In some embodiments, the concentration of B in AlScBN is greater than or equal to 0.20, e.g., y being equal to or greater than 0.20 in AlₓSc_{y}BₓN. In some embodiments, the concentration of B in AlScBN is greater than or equal to 0.5, e.g., y being equal to or greater than 0.5 in AlₓSc_{y}BₓN.

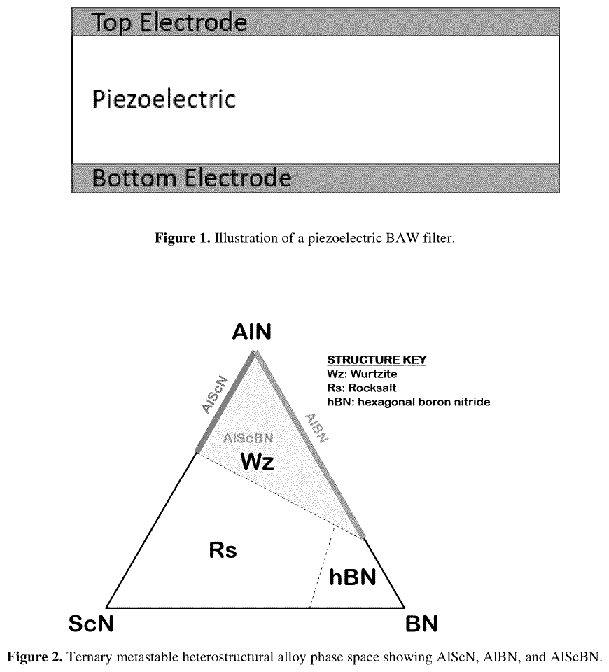

FIG. 1 illustrates a simplified diagram of a BAW filter having a disclosed piezoelectric material, according to the embodiments. As shown in FIG. 1, a piezoelectric layer (represented by “Piezoelectric”) is sandwiched between a top electrode (represented by “Top Electrode”) and a bottom electrode (represented by “Bottom Electrode”). In some embodiments, the piezoelectric layer has a thickness between about 50 nm and about 10 μm. The BAW filter may be mounted on a substrate (now shown) that reflects the acoustic wave generated by the piezoelectric layer when a bias is applied on the top and bottom electrodes. For example, the bottom electrode may be on a substrate. The top and bottom electrodes can include suitable metal, such as aluminum, alloys containing aluminum, tungsten, molybdenum, and platinum, etc.

One aspect of the present disclosure provides a BAW filter having a piezoelectric layer. In some embodiments, the piezoelectric layer includes Al₁₋ₓBₓN, which has a wurtzite structure. The value of x may be greater than 0 and less than 1. In some embodiments, the value of x is equal to or less than 0.5. For example, in some embodiments, the values of x and y may vary inversely such that the sum of x and y is equal to 1. In some embodiments, x ranges from 0 to 0.5, and y ranges from 0 to 0.5. Compared to a piezoelectric layer without B (e.g., AlN), the concentration of B (e.g., the value of y) may increase the bandwidth of the BAW filter by increasing the material coupling coefficient. Compared to the addition of Sc into AlN (e.g., AlSc)N), the addition of B may prevent or reduce the losses caused by the softening of the wurtzite lattice and reduced film quality factor caused by the addition of scandium.

The disclosed Al₁₋ₓBₓN can provide a similar increased coupling coefficient as AlScN without the lattice softening and the increased cost. For example, in the AlScN alloy system, the increase in electromechanical coupling is driven by an increase in the piezoelectric stress (e₃₃) and decrease in the lattice compliance (C₃₃). The increase in the piezoelectric stress is caused by the cation and anion planes moving closer together, which can be described by an increase in the internal wurtzite parameter u (FIG. 4). The proposed AlBN may have a similar structural evolution upon boron increase due to the increased energetic competition between the wurtzite and hexagonal boron nitride structures. In AIBN, the additional boron nitride bonds are stronger than the aluminum nitride bonds they replace, and increase the hardness of the material.

In some embodiments, the piezoelectric layer includes AlₓSc_{y}BₓN with a wurtzite structure. Depending on the application, the value of y may be any suitable number, below 0.43 or above 0.43, and the value of x may vary accordingly. At any Sc concentration (e.g., any value of y), the addition of B may increase the piezoelectric coupling and increase mechanical quality factor. For example, when the value of y is less than 0.43, the disclosed AlₓSc_{y}BₓN (e.g., value of y being greater than 0) can have similar piezoelectric coupling as AlScN, but with improved mechanical quality factors. When the value of y is greater than 0.43, the disclosed AlₓSc_{y}BₓN (e.g., value of x being greater than 0) may increase the piezoelectric coupling and improve phase stability, compared to AlScN. The addition of B may allow a high concentration (e.g., y greater than 0.43) of Sc to be incorporated into AlₓSc_{y}BₓN to achieve higher bandwidth, while maintaining similar piezoelectric properties and increasing mechanical hardness. In various embodiments, depending on the value of y, the boron concentration (e.g., the value of x) can vary accordingly. For example, the boron concentration can be desirably high to improve the mechanical hardness of AlₓSc_{y}BₓN when the Sc concentration is high. In some embodiments, the boron concentration (e.g., x) is greater than or equal to 0.2. In some embodiments, y is greater than 0.43 and x is greater than 0.2. For example, y may be about 0.5. In some embodiments, x is equal to 0.45, y is equal to 0.45, and z is equal to 0.1. In some embodiments, x is equal to 0.3, y is equal to 0.55, and z is equal to 0.15.

The use of AlScBN may enable further development at higher levels of ScN alloying then currently achievable with AlScN, and to partially compensate for the reduced lattice stiffness caused by scandium incorporation. In AlScBN, the lattice strain caused by the larger size of Sc³⁺ (0.745 Å vs 0.535 Å for Al³⁺) is compensated by the opposing lattice strain imparted by the smaller size of B³⁺ (0.11 Å vs 0.535 Å for Al³⁺), such that the wurtzite phase is stable at higher Sc concentrations than possible without B, as shown in FIG. 2. Without adding B, the AlScN has a wurtzite phase stability barrier of 43% ScN alloying, which has not been overcome with standard processing variables.

FIG. 2 shows the AlN, BN, and ScN ternary metastable heterostructural alloy phase space showing the AlScN and AlBN binary alloys and the AlScBN ternary alloys that result in wurtzite structured materials. It should be noted that FIG. 2 is a hypothetical figure and is meant to illustrate the tendency of structural changes as a function of element concentrations discussed within this application. Due to the existence as metastable heterostructural alloys the region of stability cannot be calculated by conventional thermodynamic principles and is greatly determined by processing variables. The triangular area labeled as “AlScBN” represents the wurtzite structure of Al_{z}Sc_{y}BₓN. One side of the triangular area labeled as “AIBN” represents the wurtzite structure of Al_{z}BₓN. In FIG. 2, Rs represents Rocksalt structure, hBN represents hexagonal boron nitride structure. As shown in FIG. 2, by adjusting the boron concentration, AlScBN and AlBN can have improved piezoelectric coupling and mechanical strength can be achieved for a specific application while maintaining the wurtzite structure for piezoelectric functionality.

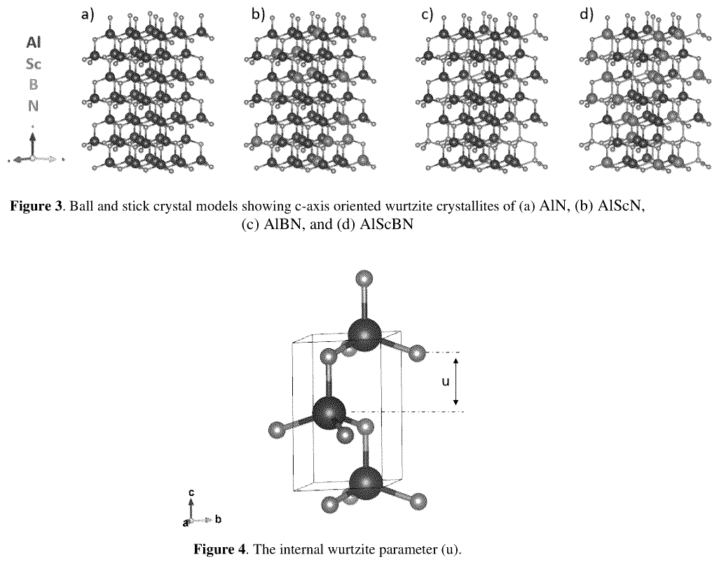

FIG. 3 shows ball and stick crystal models showing c-axis oriented wurtzite crystallites of (a) AlN and non-ordered heterostructural alloys of (b) AlScN, (c) AIBN, and (d) AlScBN at no specific concentration.

FIG. 4 illustrates the internal wurtzite parameter (u). When u is equal to c/2 the structure is identical to the hexagonal boron nitride structure, while c is the lattice constant.

Another aspect of the present disclosure provides a method for improving a figure of merit for a piezoelectric BAW filter. The piezoelectric BAW filter may include a piezoelectric layer that includes Al_{1-x-y}SC_{y}BₓN. In some embodiments, a method may include increasing the value(s) of y and/or x, while maintaining a wurtzite structure. In some embodiments, the methods may improve the piezoelectric coupling of Al_{1-x-y}Sc_{y}BₓN and maintain a wurtzite structure of Al_{z}Sc_{y}BₓN (e.g., referring back to FIG. 2). In some embodiments, the mechanical strength and stability of Al_{z}Sc_{y}BₓN may also be maintained and/or improved and maintain a wurtzite structure of Al_{z}Sc_{y}BₓN.

In some embodiments, x, and y are each a non-zero value. In some embodiments, the value of y can be increased to greater than or equal to 0.43. In some embodiments, y is equal to 0.45, and x is equal to 0.1. In some embodiments, y is equal to 0.55, and x is equal to 0.15. In some embodiments, x is greater than or equal to 0.25.

1. A piezoelectric bulk acoustic wave (BAW) filter, comprising:
a first electrode disposed over a substrate;
a piezoelectric layer disposed over the first electrode; and
a second electrode disposed over the piezoelectric layer, wherein
the piezoelectric layer comprises Al_{z}Sc_{y}BₓN;
z is equal to (1−y−x);
x is greater than 0;
y is equal to or greater than 0; and
a sum of x and y is less than or equal to 1.

2. The piezoelectric BAW filter of claim 1, wherein the piezoelectric layer has a wurtzite structure.

3. The piezoelectric BAW filter of claim 2, wherein the piezoelectric layer has a thickness between about 50 nm and about 10 μm.

4. The piezoelectric BAW filter of claim 3, wherein x is less than 0.8.

5. The piezoelectric BAW filter of claim 3, wherein x is equal to half a value of y.

6. The piezoelectric BAW filter of claim 3, wherein y is greater than or equal to 0.43.

7. The piezoelectric BAW filter of claim 3, wherein y is equal to 0.

8. The piezoelectric BSW filter of claim 3, wherein x is between about 0.08 and about 0.12, and y is between about 0.41 and about 0.47.

9. The piezoelectric BAW filter of claim 3, wherein x is between about 0.08 and about 0.12, and y is between about 0.43 and 0.47.

10. The piezoelectric BAW filter of claim 3, wherein x is between about 0.13 and about 0.15, and y is between about 0.53 and about 0.57.

11. The piezoelectric BAW filter of claim 3, wherein x is between about 0.18 and about 0.22, and y is between about 0.38 and about 0.42.

12. The piezoelectric BAW filter of claim 3, wherein x is between about 0.23 and about 0.27, and y is between about 0.48 and about 0.52.

13. The piezoelectric BAW filter of claim 3, wherein x is between about 0.28 and about 0.32, and y is between about 0.58 and about 0.62.

14. A method for improving a figure of merit for a piezoelectric bulk acoustic wave (BAW) filter having a piezoelectric layer of Al_{z}Sc_{y}BₓN, comprising:
increasing a value of x;
maintaining a wurtzite crystal structure of the piezoelectric layer,
wherein x is greater than 0;
y is equal to or greater than 0;
a sum of x and y is less than or equal to 1; and
a value of z is equal to (1−x−y).

15. The method of claim 14, where the value of x is equal to half a value of y.

16. The method of claim 14, wherein y is less than or equal to 0.43.

17. The method of claim 14, wherein x is less than or equal to 0.8.

18. The method of claim 14, wherein y is equal to 0.

19. The method of claim 14, y is between about 0.43 and 0.47, and x is between about 0.08 and about 0.12.

20. The method of claim 14, y is between about 0.53 and about 0.57, and x is between about 0.13 and about 0.17.
